(19) United States
(12) Patent Application Publication
(10) Pub. No.: US 2004/0198129 A1
(43) Pub. Date: Oct. 7, 2004

(54) Manufacturing method for increasing readable contrast of organic light emitting diode

(76) Inventors: Shu-Wen Chang, Nantou City (TW); Gwo-Sen Lin, Taichung (TW)

Correspondence Address: BIRCH STEWART KOLASCH & BIRCH, PO BOX 747, FALLS CHURCH, VA, 22040-0747, US

(21) Appl. No.: 10/405,635

(22) Filed: Apr. 3, 2003

(51) Int. Cl. H01J 9/00; H01J 9/24

(52) U.S. Cl. 445/24

(57) ABSTRACT

A manufacturing method for increasing the readable contrast of an organic light emitting diode (OLED) darkens the color scale by means of an insulating layer of the OLED to reduce the interference generated by the cathode reflection during the incidence of light source on the OLED. The technology of the present invention primarily mixes the insulating materials and additives to make a black layer material and coat such black layer material on the conductive substrate to darken the color scale of the insulating layer and then perform a yellow light process and an etching process to form the insulating layer, so that the partition of each etch area shows a dark color after the insulating layer is etched, and each etched area shows its own pixels, and thus achieving the effect of increasing the readable contrast of the OLED under strong light.

### FIELD OF INVENTION

The present invention relates to a manufacturing method for increasing readable contrast of an organic light emitting diode (OLED), more particularly to a manufacturing method of an insulating layer of an OLED.

### BACKGROUND OF THE INVENTION

Since organic light emitting diodes (OLED) feature the advantages of self light emitting, bright, thin, high response time, wide view-angle, high-resolution, applicable in flexible panel, and wide operating temperature range, therefore OLED is considered to be a new-generation flat panel display technology following the thin film transistor liquid crystal display (TFT-LCD) technology. The light emitting principle of the OLED makes use of the properties of the material to combine the electron and hole on the light emitting layer, and the released energy excites the light emitting molecules from the ground state to the excited state. When the state of the electrons drops from the excited state back to the ground state, the energy is released in form of waves, and produces light emitting components of different wavelengths; wherein the anode is ITO conductive film attached to a piece of glass or transparent plastic substrate by sputtering or evaporation; and the cathode contains metals such as Silver (Ag), magnesium (Mg), aluminum (Al), and lithium (Li). The light emitting area forms a plurality of organic films such as a hole injection layer (HIL), a hole transport layer (HTL), an organic emitting layer, and an electron transport layer (ETL) between two electrodes. It may also include other films according to the different requirements in the actual situation of mass production.

Although the organic light emitting diode has many advantages, it needs to have the self light emitting feature for the display; compared with ordinary reflective liquid crystal display (LCD) of a common handset sold in the market which only reflects the external light source for the display, the OLED panel requires a more powerful light to maintain certain contrast, particularly when it is used outdoor or under a strong light environment. The ordinary reflective LCD does not have such problem, and thus high contrast is an important topic to the OLED display.

However, the cathode of OLED components is made of metal and has the cathode reflection interference when it is used outdoor or in a bright environment. The general solution is to use a black cathode or a black layer to absorb the light, or add a polarizer with a quarter of the wavelength (a phase-shifting detection board with a quarter of the wavelength) in the OLED component. In the black cathode method, the development of black cathode material is not easy and has the shortcoming of the highly difficult manufacturing process. In the black layer method, the development of black layer is also not easy and has the same shortcoming of the highly difficult manufacturing process. Another method by adding a polarizer having a quarter of the wavelength in the OLED component will increase the thickness of the component, and adversely affects the light emitting brightness of the original OLED. In addition, the light detection board of a quarter wavelength will increase the manufacturing cost, and lower the brightness of the component. In view of the above solutions for the cathode reflection interference, they all greatly increase the manufacturing cost, and affect the yield rate of the manufacturing process during its production.

### SUMMARY OF THE INVENTION

The principal objective of the present invention to overcome the above deficiencies, and use a lower manufacturing cost to reduce the cathode reflection interference generated by the incidence of the light source on the OLED by darkening the color scale of the insulating layer of the OLED. Such technology primarily makes use of mixing the insulating material and additives for darkening the color scale to produce an insulating layer material to be coated on a conductive substrate, and the yellow light etching process forms an insulating layer such that the partitions of each etch area show a darker color after the insulating layer is etched, and each etched area shows its own pixels in order to enhance the readable contrast of the OLED under a strong light source. Such arrangement also has a significant effect on improving the display quality of the OLED panel.

### BRIEF DESCRIPTION OF THE DRAWINGS

FIG. 1 is an illustrative diagram of the flow chart of the manufacturing method of the insulating layer of the present invention.

FIGS. 2, 3, and 4 are illustrative diagrams of the method of manufacturing the insulating layer of the present invention.

FIG. 5 is an illustrative diagram of the insulating layer of the present invention.

FIGS. 6 and 7 are illustrative diagrams of the manufacturing method of the insulating layer being applied to the manufacturing method of the cathode isolating layer of the present invention.

FIG. 8 is an illustrative diagram of the manufacturing method of the insulating layer being applied to the cathode isolating layer of the present invention.

### DETAILED DESCRIPTION OF THE PREFERRED EMBODIMENTS

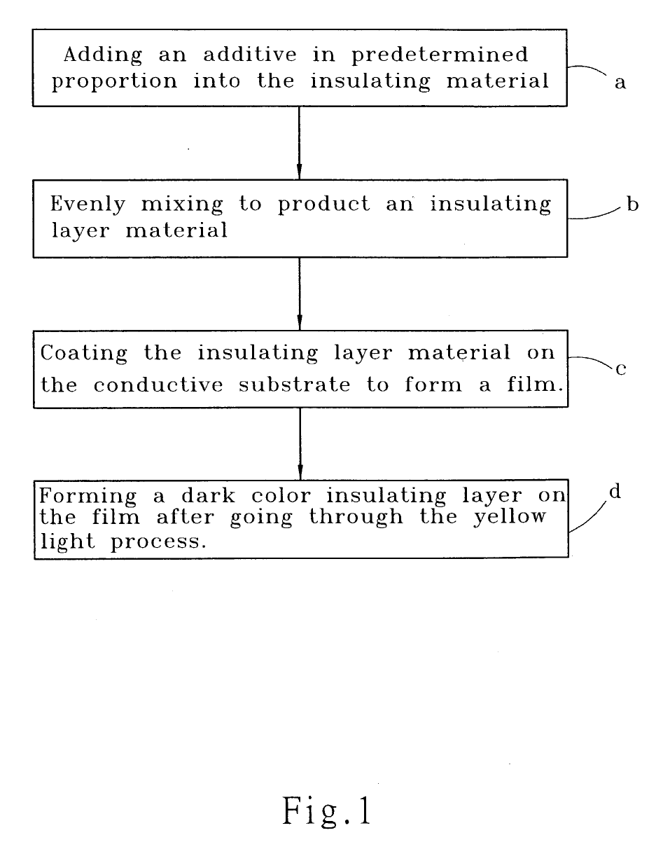

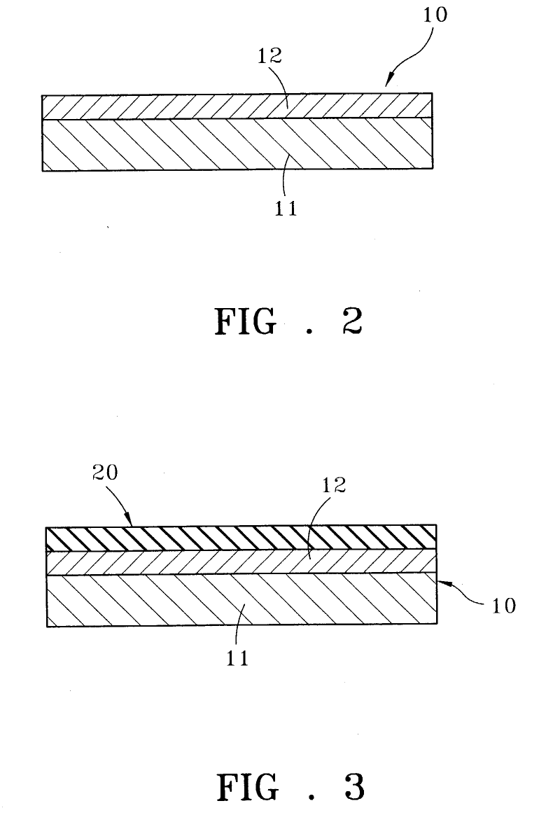

Refer to FIG. 1 for an illustrative diagram of the manufacturing method of the insulating layer of the present invention, and FIGS. 2, 3, and 4 for the illustrative diagrams of the manufacturing method of the insulating layer of the present invention. In the figures, the present invention discloses a manufacturing method for increasing the readable contrast of an OLED, and primarily darkens the color scale of an insulating layer 21 of the OLED to lower the cathode reflection interference generated by the incidence of light source on the OLED in order to enhance the video display quality of the OLED, and the insulating layer 21 is coated on a conductive substrate 10 by an insulating material and a yellow light process and etching process are performed. The detailed manufacturing procedure are described as follows:

a. Add an additive in a predetermined proportion into the original insulating material for the insulating layer 21, wherein the insulating material has a development feature and low dielectric photoresist material, and the additive is a black dye or a dark color substance having equivalent darkening effect, and such additive is an insulator; and the proportion of the additive and the insulating material is adjusted according to the desired color without affecting the properties of the insulating material.

b. Evenly mix the materials listed in the Step a to produce the material for the insulating layer 21, which is the required material for the insulating layer 21 between the OLED components.

c. Take a conductive substrate 10, which is a substrate 11 having patterned anode conductive layer 12 (as shown in FIG. 2) and coat the material for the insulating layer 21 of Step b onto the conductive substrate 10 to form a film 20 of a specific thickness (as shown in FIG. 3).

d. A yellow light process and etching process are performed on the conductive substrate 10 with coated film produced in Step c, such that the film 20 forms an insulating layer 21 (as shown in FIG. 4) and defines a darker color partition 211 of each etched area on the insulating layer 21. The partition 211 of the insulating layer 21 corresponsive to the pixel interval 30 is similar to a dark color fence surrounding each pixel.

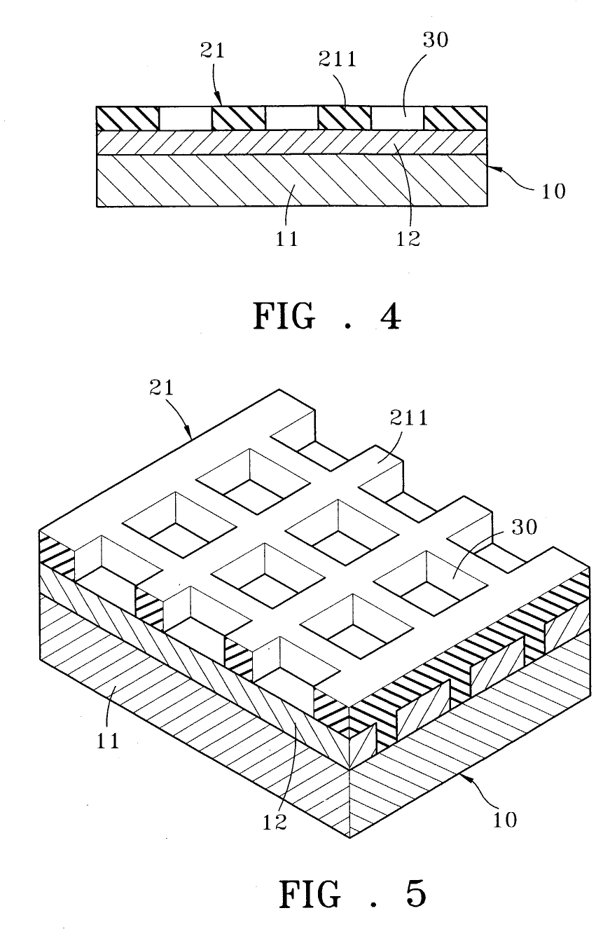

Please refer to FIG. 5 for an illustrative diagram of the insulating layer of the present invention. In the figure, it shows the insulating layer 21 produced in the manufacturing method of the present invention; the partition 211 of each etched area of the insulating layer 21 shows a dark color, and the partition 211 of the insulating layer 21 corresponsive to the pixel interval 30 is similar to a dark color fence surrounding each pixel. When the OLED component is packaged as a monitor, such dark color insulating layer 21 can suppress the cathode reflection interference on the panel. In other words, when the panel has a cathode reflection, such reflection will be blocked by the partition 211 of the dark color insulating layer 21, and thus the cathode reflection produced between pixels will not have the interference. When the monitor is used outdoor or under strong light, it can enhance the effect of readable contrast of the OLED panel, which is very helpful on improving the display quality of the panel.

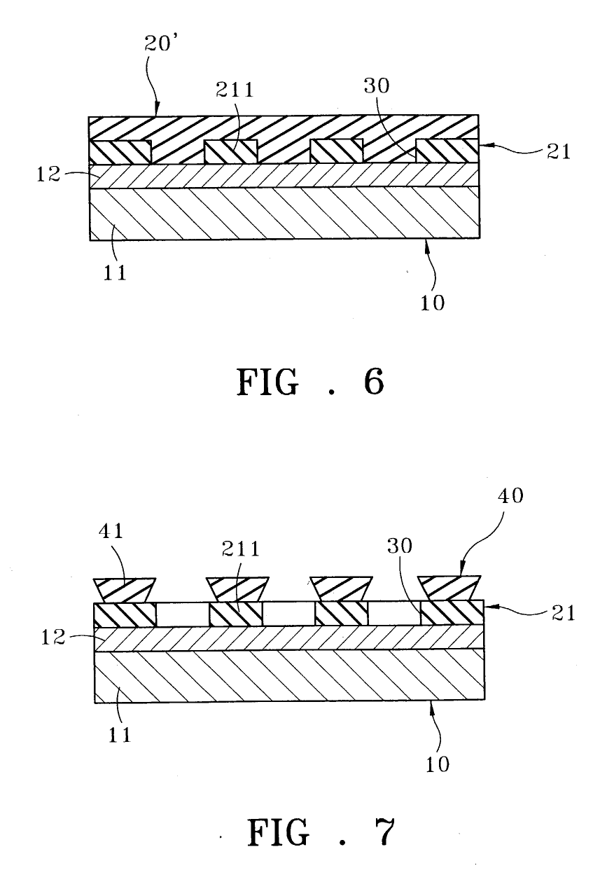

Please refer to FIG. 6 for the illustrative diagram of the manufacturing method of the insulating layer being applied to the manufacturing method of the cathode isolating layer. In the figure, the present invention uses the manufacturing method of producing a conductive substrate 10 of the insulating layer 21 as shown in FIG. 4 and coat an insulating layer material by the present invention method to form a film 20′, and a yellow light process and an etching process are performed on the conductive substrate 10 of the insulating layer 21 so that the film 20′ produces a cathode isolating layer 40 as shown in FIG. 7. The pattern formed on the cathode isolating layer 40 is used in an isolating wall 40 of the isolating cathode conductive layer 60.

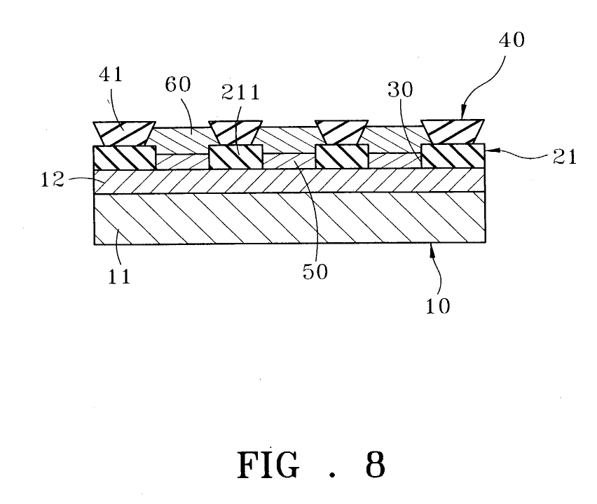

Please refer to FIG. 8 for the illustrative diagram of the manufacturing method of the insulating layer being applied to the cathode isolating layer. In the figure, the cathode isolating layer 40 is on top of the insulating layer 21, and the pattern on the isolating wall 41 of the cathode isolating layer 40 is in the bar shape and disposed on the partition 211 of the insulating layer 21 to facilitate the following manufacturing processes of the OLED component. An organic light emitting layer 50 is produced in the pixel area 30, and then a cathode conductive layer 60 is produced between the isolating walls 41 along the cathode conductive layer 60 on the organic light emitting layer 50. An organic light emitting layer in the pixel interval 30 is included between the cathode conductive layer 60 and the anode conductive layer of the substrate

In the OLED component manufacturing process, the manufacturing method of the cathode isolating layer 40 of the present invention is applied. After the OLED component is packaged, the cathode reflection interference of the panel is suppressed for the entire insulating layer 21. In other word, the whole insulating layer 21 uses the manufacturing method of the present invention, which gives a better suppression effect on the cathode reflection interference of the panel, and provides a consistency for the manufacturing process to give a more convenient way of controlling the materials.

Those skilled in the art will readily recognize that these and various other modifications and changes may be made to the present invention without strictly following the exemplary application illustrated and described herein and without departing from the true spirit and scope of the present invention, which is set forth in the following claims.

What is claimed is:

1. A manufacturing method for increasing readable contrast of organic light emitting diode (OLED) by darkening the color scale of an insulating layer of the OLED to lower the cathode reflection interference produced by the incidence of light source on the OLED and improve the video display quality of the OLED, said manufacturing method comprising the steps of:
a. adding an additive in a predetermined proportion into the original insulating material for the insulating layer;
b. evenly mixing the materials in Step a to produce an insulating layer material;
c. taking a conductive substrate, said substrate having a patterned anode conductive layer; coating the insulating layer material of Step b onto said conductive substrate to form a film of a fixed thickness;
d. a yellow light process and an etching process being performed on the conductive substrate with coated film produced in Step c, such that the film forming an insulating layer and defining a dark color partition for each etched area on the insulating layer.

2. The manufacturing method for increasing readable contrast of organic light emitting diode (OLED) of claim 1, wherein said insulating material is a photoresist material having the development feature and low dielectric property.

3. The manufacturing method for increasing readable contrast of organic light emitting diode (OLED) of claim 1, wherein said additive is a black dye or dark color matter having the equivalent effect of darkening the color scale.

4. The manufacturing method for increasing readable contrast of organic light emitting diode (OLED) of claim 1, wherein said additive is an insulator.

5. The manufacturing method for increasing readable contrast of organic light emitting diode (OLED) of claim 1, wherein said additive and insulating material having an adjustable predetermined proportion according to the required color scale without affecting the nature of the insulating material.

6. The manufacturing method for increasing readable contrast of organic light emitting diode (OLED) of claim 1, wherein said insulating layer has an additional insulating layer material coated on the insulating layer to form a film, thereby forming a cathode isolating layer having an isolating wall after going through a yellow light process and an etching process.

7. An insulating layer for increasing readable contrast of organic light emitting diode (OLED), said insulating layer being produced by coating a insulating layer material on a conductive substrate and performing a yellow light process and an etching process, wherein:
said insulating layer material is a mixture of an insulating material and an additive for darkening the color scale, such that a partition of each etched area of the insulating layer shows a dark color, and each etched area shows its own pixels to enhance the effect of readable contrast of the OLED.

8. The insulating layer for increasing readable contrast of organic light emitting diode (OLED) of claim 7, wherein said insulating material is a photoresist material having a development feature and low dielectric property.

9. The insulating layer for increasing readable contrast of organic light emitting diode (OLED) of claim 7, wherein said additive is a black dye or dark color matter having the equivalent effect of darkening the color scale.

10. The insulating layer for increasing readable contrast of organic light emitting diode (OLED) of claim 7, wherein said additive is an insulator.

11. The insulating layer for increasing readable contrast of organic light emitting diode (OLED) of claim 7, wherein said additive and insulating material having an adjustable predetermined proportion according to the required color scale without affecting the nature of the insulating material.
